(19) United States
(12) Patent Application Publication
(10) Pub. No.: US 2024/0339480 A1
(43) Pub. Date: Oct. 10, 2024

(54) DETECTION DEVICE AND MULTILAYER STRUCTURE

(71) Applicant: Japan Display Inc., Tokyo (JP)

(72) Inventors: Shigeru TABATAKE, Tokyo (JP); Tetsuya YAMAMOTO, Tokyo (JP); Junko NAGASAWA, Tokyo (JP)

(21) Appl. No.: 18/746,236

(22) Filed: Jun. 18, 2024

Related U.S. Application Data
(63) Continuation of application No. PCT/JP2022/042082, filed on Nov. 11, 2022.

(30) Foreign Application Priority Data
Dec. 22, 2021 (JP) 2021-208686

(51) Int. Cl. H01L 27/146

(52) U.S. Cl. CPC H01L 27/14643; H01L 27/14621; H01L 27/14623; H01L 27/14627

(57) ABSTRACT

A detection device includes a substrate having a detection region, a plurality of photodiodes provided in the detection region, a first light-transmitting resin layer that is provided so as to cover the photodiodes and comprises a flat portion and a periphery that is formed to be gradually thinner toward an end on a peripheral side of the first light-transmitting resin layer, a light-blocking layer that is provided on the first light-transmitting resin layer and provided with an opening in a region overlapping each of the photodiodes, and a plurality of lenses provided so as to overlap the respective photodiodes. In a region of the periphery of the first light-transmitting resin layer extending along a predetermined side, an asperity pattern is repeatedly formed in a direction intersecting the side and repeatedly formed in a direction along the side.

### CROSS-REFERENCE TO RELATED APPLICATION

This application is a continuation of International Patent Application No. PCT/JP2022/042082 filed on Nov. 11, 2022 which designates the United States, incorporated herein by reference, and which claims the benefit of priority from Japanese Patent Application No. 2021-208686 filed on Dec. 22, 2021, incorporated herein by reference.

### BACKGROUND

### 1. Technical Field

The present disclosure relates to a detection device and a multilayer structure.

### 2. Description of the Related Art

United States Patent Application Publication No. 2019/0080138 describes a display panel that includes a lens array in which a plurality of lenses are arranged, an optical sensor array in which a plurality of optical sensors are arranged, and a pinhole array provided between the lens array and the optical sensor array.

In a detection device in which the pinhole array and the lens array are stacked above the optical sensor array, when, for example, a light-blocking layer and the lens are formed above a light-transmitting resin layer, a step formed at an end on the peripheral side of the light-transmitting resin layer may cause variations in shapes of the pinholes formed in the light-blocking layer and the lenses. The variations in shapes of the pinholes and the lenses vary the state of light transmitted through the lenses and focused on the sensors. This phenomenon may cause deterioration in detection accuracy.

It is an object of the present disclosure to provide a detection device and a multilayer structure capable of reducing the variations in shapes of optical elements.

### SUMMARY

A detection device according to an embodiment of the present disclosure includes a substrate having a detection region, a plurality of photodiodes provided in the detection region, a first light-transmitting resin layer that is provided so as to cover the photodiodes and comprises a flat portion and a periphery that is formed to be gradually thinner toward an end on a peripheral side of the first light-transmitting resin layer, a light-blocking layer that is provided on the first light-transmitting resin layer and provided with an opening in a region overlapping each of the photodiodes, and a plurality of lenses provided so as to overlap the respective photodiodes. In a region of the periphery of the first light-transmitting resin layer extending along a predetermined side, an asperity pattern is repeatedly formed in a direction intersecting the side and repeatedly formed in a direction along the side.

A multilayer structure according to an embodiment of the present disclosure includes a substrate, at least one light-transmitting resin layer that is stacked above the substrate and comprises a flat portion and a periphery that is formed to be gradually thinner toward an end on a peripheral side of the light-transmitting resin layer, and an optical functional layer stacked on the light-transmitting resin layer. In a region of the periphery of the light-transmitting resin layer extending along a predetermined side, an asperity pattern is repeatedly formed in a direction intersecting the side and repeatedly formed in a direction along the side.

### BRIEF DESCRIPTION OF THE DRAWINGS

FIG. 1A is a sectional view illustrating a schematic sectional configuration of a detection apparatus having an illumination device, the detection apparatus including a detection device according to an embodiment of the present disclosure;

FIG. 1B is a sectional view illustrating a schematic sectional configuration of the detection apparatus having an illumination device, the detection apparatus including the detection device according to a first modification;

FIG. 1C is a sectional view illustrating a schematic sectional configuration of the detection apparatus having an illumination device, the detection apparatus including the detection device according to a second modification;

FIG. 1D is a sectional view illustrating a schematic sectional configuration of the detection apparatus having an illumination device, the detection apparatus including the detection device according to a third modification;

FIG. 2 is a plan view illustrating the detection device according to the embodiment;

FIG. 3 is a sectional view along III-III′ of FIG. 2;

FIG. 4 is a plan view illustrating an optical filter according to the embodiment;

FIG. 5 is a sectional view illustrating the optical filter;

FIG. 6 is a sectional view schematically illustrating a configuration of an array substrate attached to a display panel;

FIG. 7 is a plan view schematically illustrating the array substrate and the optical filter in a peripheral region;

FIG. 8 is a sectional view illustrating the optical filter in the peripheral region;

FIG. 9 is a plan view illustrating a portion of the periphery of a first light-transmitting resin layer in an enlarged manner;

FIG. 10 is a sectional view along X-X′ of FIG. 9;

FIG. 11 is a plan view schematically illustrating a portion of a photomask used for manufacturing the first light-transmitting resin layer;

FIG. 12 is a sectional view for explaining asperity patterns in a first direction of the first light-transmitting resin layer;

FIG. 13 is a sectional view along XIII-XIII′ of FIG. 9, and is a sectional view for explaining an asperity pattern in a second direction of the first light-transmitting resin layer;

FIG. 14 is a plan view for explaining an example of the asperity patterns on the periphery of the first light-transmitting resin layer;

FIG. 15 is a plan view for explaining an example of the asperity patterns on a corner of the periphery of the first light-transmitting resin layer;

FIG. 16 is a plan view schematically illustrating a portion of the photomask used for manufacturing the first light-transmitting resin layer illustrated in FIGS. 14 and 15;

FIG. 17 is a plan view illustrating a detection element; and

FIG. 18 is a sectional view along XVIII-XVIII′ of FIG. 17.

### DETAILED DESCRIPTION

The following describes a mode (embodiment) for carrying out the present disclosure in detail with reference to the drawings. The present disclosure is not limited to the description of the embodiment to be given below. Components to be described below include those easily conceivable by those skilled in the art or those substantially identical thereto. In addition, the components to be described below can be combined as appropriate. What is disclosed herein is merely an example, and the present disclosure naturally encompasses appropriate modifications easily conceivable by those skilled in the art while maintaining the gist of the present disclosure. To further clarify the description, the drawings may schematically illustrate, for example, widths, thicknesses, and shapes of various parts as compared with actual aspects thereof. However, they are merely examples, and interpretation of the present disclosure is not limited thereto. The same component as that described with reference to an already mentioned drawing is denoted by the same reference numeral through the present disclosure and the drawings, and detailed description thereof may not be repeated where appropriate.

In the present specification and claims, in expressing an aspect of disposing a certain structure above another structure, a case of simply expressing “above” includes both a case of disposing the certain structure immediately above the other structure so as to contact the other structure and a case of disposing the certain structure above the other structure with still another structure interposed therebetween, unless otherwise specified.

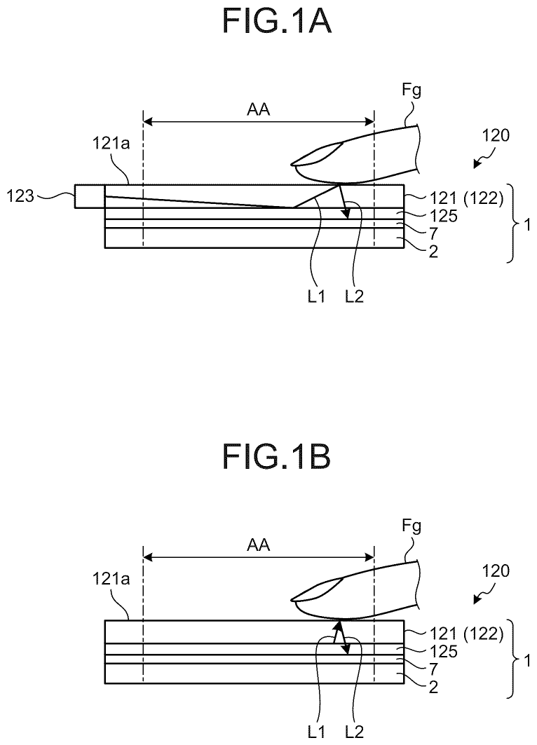

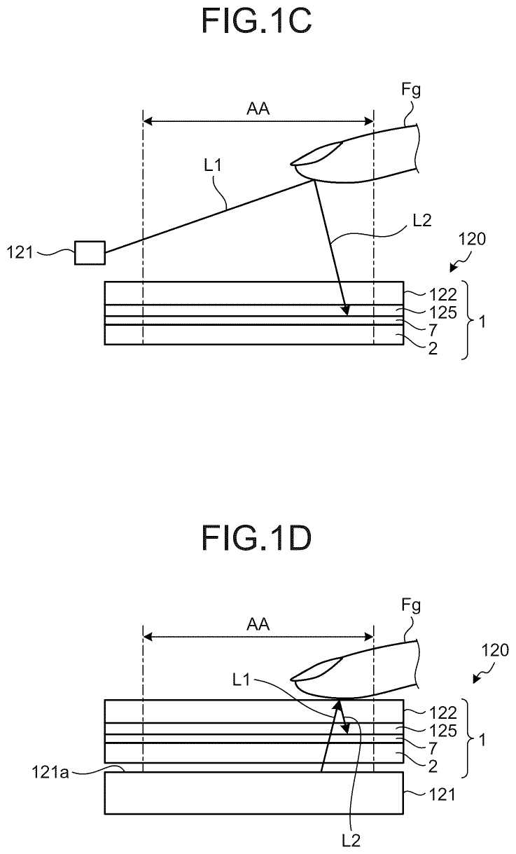

FIG. 1A is a sectional view illustrating a schematic sectional configuration of a detection apparatus having an illumination device, the detection apparatus including a detection device according to an embodiment of the present disclosure. FIG. 1B is a sectional view illustrating a schematic sectional configuration of the detection apparatus having an illumination device, the detection apparatus including the detection device according to a first modification. FIG. 1C is a sectional view illustrating a schematic sectional configuration of the detection apparatus having an illumination device, the detection apparatus including the detection device according to a second modification. FIG. 1D is a sectional view illustrating a schematic sectional configuration of the detection apparatus having an illumination device, the detection apparatus including the detection device according to a third modification.

As illustrated in FIG. 1A, a detection apparatus 120 having an illumination device includes a detection device 1 and an illumination device 121. The detection device 1 includes an array substrate 2, an optical filter 7, an adhesive layer 125, and a cover member 122. That is, the array substrate 2, the optical filter 7, the adhesive layer 125, and the cover member 122 are stacked in this order in a direction orthogonal to a surface of the array substrate 2. As will be described later, the cover member 122 of the detection device 1 may be replaced with the illumination device 121. The adhesive layer 125 only needs to bond the optical filter 7 to the cover member 122, and the detection device 1 may have a structure without the adhesive layer 125 in a region corresponding to a detection region AA. When the adhesive layer 125 is absent in the detection region AA, the detection device 1 has a structure in which the adhesive layer 125 bonds the cover member 122 to the optical filter 7 in a region corresponding to a peripheral region GA outside the detection region AA. The adhesive layer 125 provided in the detection region AA may be simply paraphrased as a protective layer for the optical filter 7.

As illustrated in FIG. 1A, the illumination device 121 may be, for example, what is called a side light-type front light that uses the cover member 122 as a light guide plate provided in a position corresponding to the detection region AA of the detection device 1 and includes a plurality of light sources 123 arranged at one end or both ends of the cover member 122. That is, the cover member 122 has a light-emitting surface 121a for emitting light, and serves as one component of the illumination device 121. The illumination device 121 emits light L1 from the light-emitting surface 121a of the cover member 122 toward a finger Fg that serves as a detection target. For example, light-emitting diodes (LEDs) that emit light in a predetermined color are used as the light sources.

As illustrated in FIG. 1B, the illumination device 121 may include the light sources (for example, LEDs) provided in the detection region AA of the detection device 1. The illumination device 121 including the light sources also serves as the cover member 122.

The illumination device 121 is not limited to the example of FIG. 1B. As illustrated in FIG. 1C, the illumination device 121 may be provided on a lateral side or an upper side of the cover member 122, and may emit the light L1 to the finger Fg from the lateral side or the upper side of the finger Fg.

Furthermore, as illustrated in FIG. 1D, the illumination device 121 may be what is called a direct-type backlight that includes the light sources (for example, LEDs) provided in the detection region of the detection device 1.

The light L1 emitted from the illumination device 121 is reflected as light L2 by the finger Fg serving as the detection target. The detection device 1 detects the light L2 reflected by the finger Fg to detect asperities (such as a fingerprint) on a surface of the finger Fg. The detection device 1 may further detect information on a living body by detecting the light L2 reflected in the finger Fg, in addition to detecting the fingerprint. Examples of the information on the living body include a vascular image, pulsation, and pulse waves of, for example, veins. The color of the light L1 from the illumination device 121 may be changed depending on the detection target.

The cover member 122 is a member for protecting the array substrate 2 and the optical filter 7, and covers the array substrate 2 and the optical filter 7. The illumination device 121 may have a structure to double as the cover member 122, as described above. In the structures illustrated in FIGS. 1C and 1D in which the cover member 122 is separate from the illumination device 121, the cover member 122 is a glass substrate, for example. The cover member 122 is not limited to the glass substrate, and may be a resin substrate, for example. The cover member 122 need not be provided. In that case, the surfaces of the array substrate 2 and the optical filter 7 are provided with a protective layer of, for example, an insulating film, and the finger Fg contacts the protective layer of the detection device 1.

The detection apparatus 120 having an illumination device illustrated in FIG. 1B may be provided with a display panel instead of the illumination device 121. The display panel may be, for example, an organic electroluminescent (EL) (organic light-emitting diode (OLED)) display panel or an inorganic EL (micro-LED or mini-LED) display panel. Alternatively, the display panel may be a liquid crystal display (LCD) panel using liquid crystal elements as display elements or an electrophoretic display (EPD) panel using electrophoretic elements as the display elements. Also in this case, the fingerprint of the finger Fg and the information on the living body can be detected based on the light L2 obtained by reflecting display light (light L1) emitted from the display panel on and in the finger Fg.

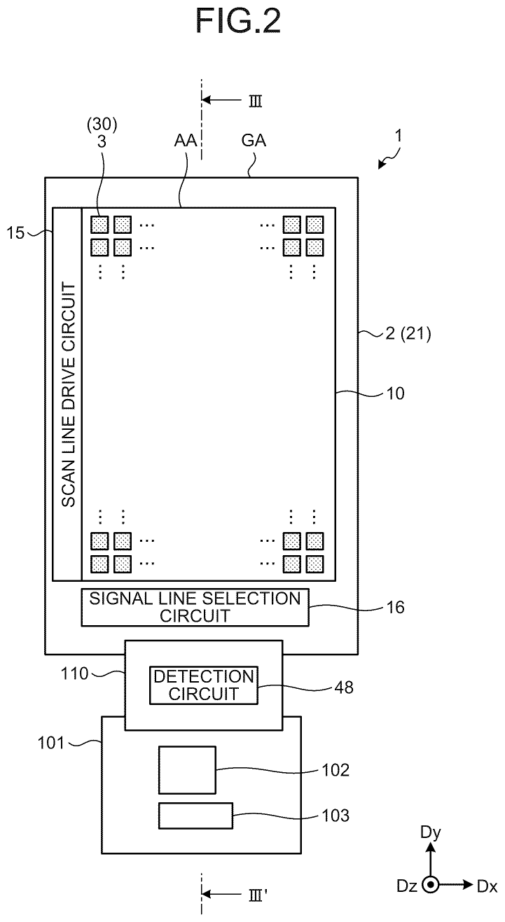

FIG. 2 is a plan view illustrating the detection device according to the embodiment. A first direction Dx illustrated in FIG. 2 and the subsequent drawings is one direction in a plane parallel to a substrate 21. A second direction Dy is one direction in the plane parallel to the substrate 21, and is a direction orthogonal to the first direction Dx. The second direction Dy may non-orthogonally intersect the first direction Dx. A third direction Dz is a direction orthogonal to the first direction Dx and the second direction Dy, and is a direction normal to the substrate 21. The term “plan view” refers to a positional relation as viewed from the third direction Dz.

As illustrated in FIG. 2, the detection device 1 includes the array substrate 2 (substrate 21), a sensor unit 10, a scan line drive circuit 15, a signal line selection circuit 16, a detection circuit 48, a control circuit 102, and a power supply circuit 103.

The substrate 21 is electrically coupled to a control substrate 101 through a wiring substrate 110. The wiring substrate 110 is, for example, a flexible printed circuit board or a rigid circuit board. The wiring substrate 110 is provided with the detection circuit 48. The control substrate 101 is provided with the control circuit 102 and the power supply circuit 103. The control circuit 102 is a field-programmable gate array (FPGA), for example. The control circuit 102 supplies control signals to the sensor unit 10, the scan line drive circuit 15, and the signal line selection circuit 16 to control an operation of the sensor unit 10. The power supply circuit 103 supplies voltage signals including, for example, a power supply potential VDD and a reference potential VCOM to the sensor unit 10, the scan line drive circuit 15, and the signal line selection circuit 16. In the present embodiment, the case is exemplified where the detection circuit 48 is disposed on the wiring substrate 110, but the present disclosure is not limited to this case. The detection circuit 48 may be disposed on the substrate 21.

The substrate 21 has the detection region AA and the peripheral region GA. The detection region AA and the peripheral region GA extend in planar directions parallel to the substrate 21. Elements (detection elements 3) of the sensor unit 10 are provided in the detection region AA. The peripheral region GA is a region outside the detection region AA, and is a region not provided with the elements (detection elements 3) that each serve as an optical sensor. That is, the peripheral region GA is a region between the outer periphery of the detection region AA and the ends of the substrate 21. The scan line drive circuit 15 and the signal line selection circuit 16 are provided in the peripheral region GA. The scan line drive circuit 15 is provided in a region extending along the second direction Dy in the peripheral region GA. The signal line selection circuit 16 is provided in a region extending along the first direction Dx in the peripheral region GA, and is provided between the sensor unit 10 and the detection circuit 48.

Each of the detection elements 3 of the sensor unit 10 is an optical sensor including a photodiode 30 as a sensor element. The photodiode 30 is a photoelectric conversion element, and outputs an electric signal corresponding to light irradiating each of the photodiodes 30. More specifically, the photodiode 30 is a positive-intrinsic-negative (PIN) photodiode. The photodiode 30 may be an organic photodiode (OPD). The detection elements 3 are arranged in a matrix having a row-column configuration in the detection region AA. The photodiodes 30 included in the detection elements 3 perform the detection in response to gate drive signals supplied from the scan line drive circuit 15. Each of the photodiodes 30 outputs the electric signal corresponding to the light irradiating the photodiode 30 as a detection signal to the signal line selection circuit 16. The detection device 1 detects the information on the living body based on the detection signals received from the photodiodes 30.

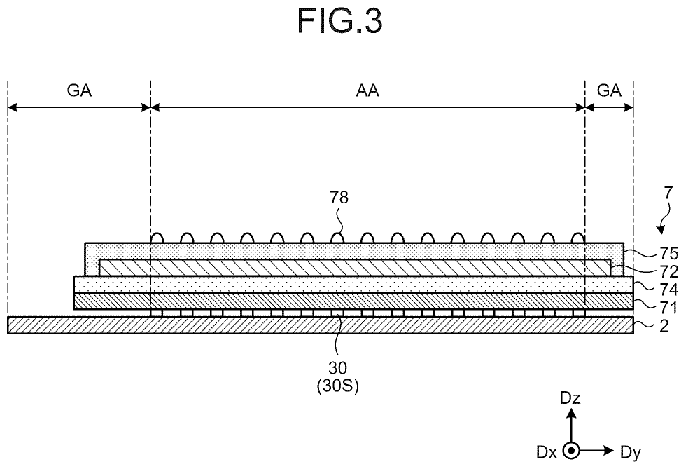

FIG. 3 is a sectional view along III-III′ of FIG. 2. FIG. 3 schematically illustrates a multilayer configuration of the array substrate 2, the photodiodes 30, and the optical filter 7.

As illustrated in FIG. 3, the optical filter 7 is provided on the photodiodes 30 (partial photodiodes 30S). The optical filter 7 includes a first light-blocking layer 71, a second light-blocking layer 72, a first light-transmitting resin layer 74, a second light-transmitting resin layer 75, and lenses 78. The optical filter 7 illustrated in FIG. 3 is merely schematically illustrated, and a detailed multilayer configuration of the optical filter 7 will be described later. The optical filter 7 is an optical element that transmits, toward the photodiodes 30, components of the light L2 reflected by an object to be detected, such as the finger Fg, that travel in the third direction Dz, and blocks components of the light L2 that travel in oblique directions. The optical filter 7 is also called a collimating aperture or a collimator.

The optical filter 7 is provided over the detection region AA and the peripheral region GA. The optical filter 7 includes, on an upper surface thereof, the lenses 78. The lenses 78 are provided in the detection region AA, and are provided so as to overlap the respective photodiodes 30 (partial photodiodes 30S). The light L2 reflected by the object to be detected such as the finger Fg is condensed by the lenses 78, and irradiates the photodiodes 30 (partial photodiodes 30S) corresponding to the respective lenses 78.

While the lenses 78 are not provided in the peripheral region GA, dummy lenses that do not serve as optical elements may be provided in the peripheral region GA. The dummy lenses are provided so as not to overlap the photodiodes 30 (partial photodiodes 30S) in the detection region AA. The dummy lenses are formed to have the same configuration as that of the lenses 78. Providing the dummy lenses can improve the shape stability of the lenses 78 in the detection region AA.

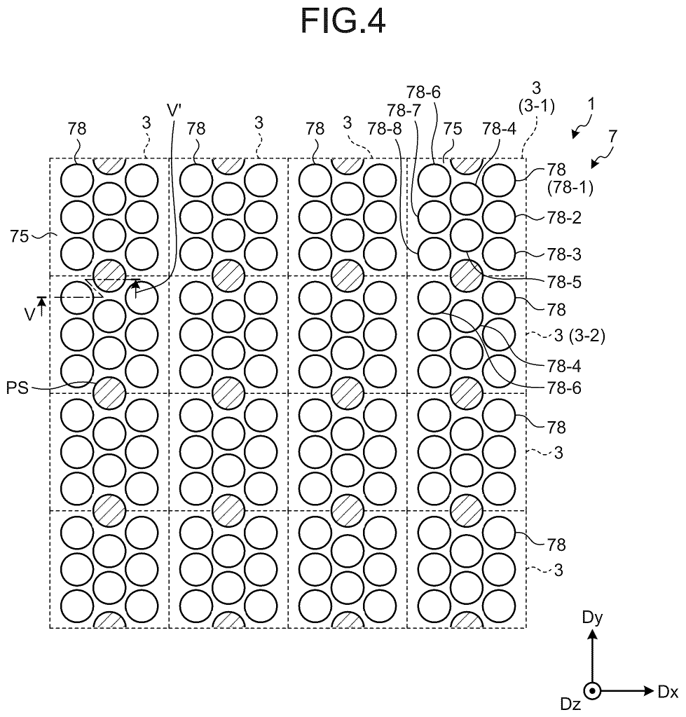

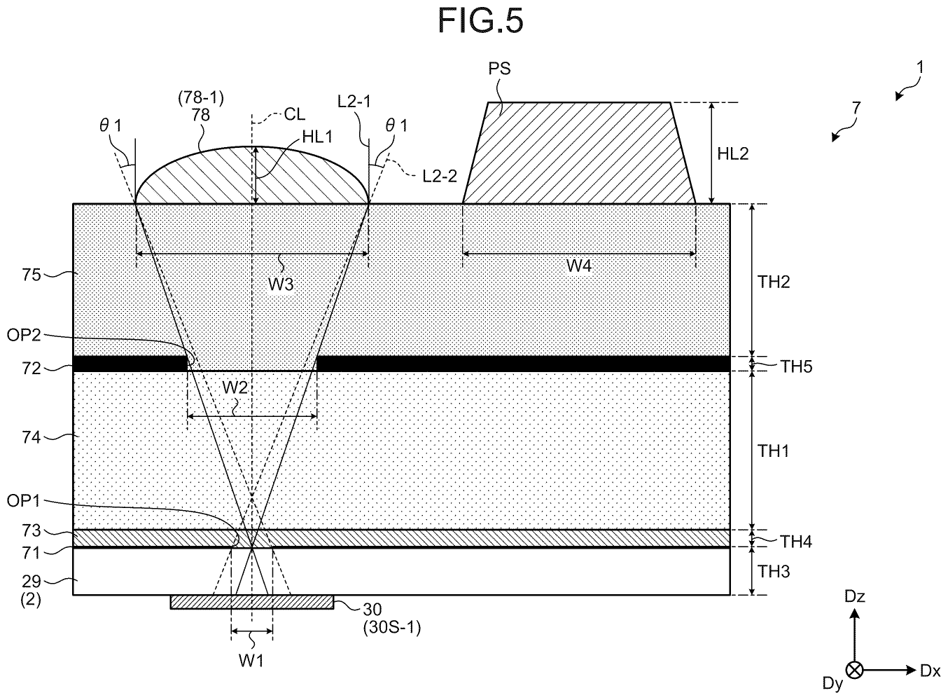

The following describes a detailed configuration of the detection elements 3 and the optical filter 7. FIG. 4 is a plan view illustrating the optical filter according to the embodiment.

As illustrated in FIG. 4, the optical filter 7 is provided so as to cover the detection elements 3 (photodiodes 30) arranged in a matrix having a row-column configuration. The optical filter 7 includes the first light-transmitting resin layer 74 and the second light-transmitting resin layer 75 that cover the detection elements 3, and includes the lenses 78 provided for each of the detection elements 3. The optical filter 7 further includes a plurality of projections PS provided between the adjacent lenses 78.

More than one of the lenses 78 are arranged for each of the detection elements 3. In the example illustrated in FIG. 4, eight lenses 78 of 78-1, 78-2, . . . , 78-8 are provided for each of the detection elements 3. The lenses 78-1, 78-2, . . . , 78-8 are arranged in a triangular lattice pattern. As will be described later, each of the detection elements 3 has a plurality of detection regions (partial photodiodes 30S), thus having a structure in which the lenses 78 correspond to the respective detection regions in each of the detection elements 3.

The number of the lenses 78 arranged in each of the detection elements 3 may be seven or smaller, or nine or larger so as to match the number of the detection regions (partial photodiodes 30S to be described later). The lenses 78 may be provided in a number different from that of the detection regions. The arrangement of the lenses 78 may also be changed as appropriate depending on the configuration of the photodiodes 30.

The projection PS is a columnar member formed in the same circular shape as that of the lens 78 in plan view. The projection PS is used as a spacer when the cover member 122 and the like are attached above the optical filter 7. Alternatively, the projection PS is used as a spacer when the array substrate 2 is stacked on another substrate in the manufacturing process of the detection device 1. Each of the projections PS is provided so as to be surrounded by six of the lenses 78. More specifically, the projection PS is disposed between the lens 78-4 and the lens 78-5 in the second direction Dy. The projection PS is disposed between the lenses 78-1 and 78-3 and the lenses 78-6 and 78-8 in the first direction Dx. The projections PS are arranged in a triangular lattice pattern with the lenses 78, and efficiently arranged in spaces between the lenses 78.

The projection PS is provided at a boundary between the detection elements 3 adjacent in the second direction Dy (for example, at a boundary between the detection elements 3-1 and 3-2). In other words, the projection PS is provided between the photodiodes 30 adjacent in the second direction Dy in plan view. The number of the projections PS is smaller than the number of the lenses 78. The projections PS are provided so as not to overlap the partial photodiodes 30S of the photodiodes 30.

However, the arrangement and the number of the projections PS can be changed as appropriate. For example, the projection PS may be provided at a boundary between the detection elements 3 adjacent in the first direction Dx. Although each of the detection elements 3 is provided with the projection PS, one or some of the detection elements 3 may be provided with no projection PS. The projection PS may have a different shape and size from those of the lens 78.

FIG. 5 is a sectional view illustrating the optical filter. FIG. 5 is a sectional view along V-V′ of FIG. 4. FIG. 5 illustrates the configuration of the array substrate 2 in a simplified manner, and schematically illustrates the photodiode 30 (partial photodiode 30S-1) and a protective film 29 (organic protective film) covering the photodiode 30.

As illustrated in FIG. 5, the optical filter 7 includes the first light-blocking layer 71, the second light-blocking layer 72, a filter layer 73 (infrared (IR) cut filter layer), the first light-transmitting resin layer 74, the second light-transmitting resin layer 75, and the lens 78. In the present embodiment, the first light-blocking layer 71, the filter layer 73, the first light-transmitting resin layer 74, the second light-blocking layer 72, the second light-transmitting resin layer 75, and the lens 78 are stacked in this order above the protective film 29. The projection PS is formed integrally with the optical filter 7, and is provided in the same layer as that of the lens 78 on the second light-transmitting resin layer 75.

The lens 78 is provided in a region overlapping the partial photodiode 30S-1 of one photodiode 30. The lens 78 is a convex lens. An optical axis CL of the lens 78 is provided in a direction parallel to the third direction Dz, and intersects the partial photodiode 30S-1. The lens 78 is provided on the second light-transmitting resin layer 75 so as to be in direct contact therewith. In other words, the second light-transmitting resin layer 75 is provided between the second light-blocking layer 72 and the lens 78. In the present embodiment, no light-blocking layer or the like is provided on the second light-transmitting resin layer 75 between the adjacent lenses 78.

The first light-blocking layer 71 is provided on the protective film 29 of the array substrate 2 so as to be in direct contact therewith. In other words, the first light-blocking layer 71 is provided between the photodiode 30 and the lens 78 in the third direction Dz. The first light-blocking layer 71 is provided with a first opening OP1 in a region overlapping the photodiode 30. The first opening OP1 is formed in a region overlapping the optical axis CL.

The first light-blocking layer 71 is formed of, for example, a metal material such as molybdenum (Mo). This configuration allows the first light-blocking layer 71 to reflect components of the light L2 traveling in the oblique directions other than the light L2 that passes through the first opening OP1. Since the first light-blocking layer 71 is formed of a metal material, a width W1 (diameter) in the first direction Dx of the first opening OP1 can be accurately formed. Therefore, the first opening OP1 can be provided correspondingly to the photodiode 30 even when the arrangement pitch and the area of the photodiodes 30 are small.

In addition, unlike the second light-blocking layer 72 formed of a resin material to be described later, the first light-blocking layer 71 is formed of a metal material. Therefore, the first light-blocking layer 71 can be formed to be thinner than the second light-blocking layer 72 is and can have the first opening OP1 formed therein that is smaller than a second opening OP2 formed in the second light-blocking layer 72. The thickness of the first light-blocking layer 71 is equal to or smaller than one tenth the thickness of the second light-blocking layer 72. The first light-blocking layer 71 is formed to have a much smaller thickness than that of the second light-blocking layer 72. As an example, the thickness of the first light-blocking layer 71 is equal to or larger than 0.055 μm, and is, for example, 0.065 μm; and a thickness TH5 of the second light-blocking layer (refer to FIG. 5) is, for example, 1 μm. The first light-blocking layer 71 is formed to have a much smaller thickness than the thickness TH5 of the second light-blocking layer 72.

The filter layer 73 is provided on the first light-blocking layer 71 so as to be in direct contact therewith, and is provided between the first light-blocking layer 71 and the first light-transmitting resin layer 74 in the third direction Dz. The filter layer 73 is a filter that blocks light in a predetermined wavelength band. The filter layer 73 is, for example, an IR cut filter that is formed of a resin material colored in green and blocks infrared rays. Thus, the optical filter 7 can improve the detection sensitivity by allowing, for example, a component of the light L2 in a wavelength band required for the fingerprint detection to enter the photodiode 30.

The first light-transmitting resin layer 74 is provided on the filter layer 73 so as to be in direct contact therewith, and is provided between the first light-blocking layer 71 and the second light-blocking layer 72 in the third direction Dz. The first light-transmitting resin layer 74 and the second light-transmitting resin layer 75 are formed of a light-transmitting acrylic resin, for example.

The second light-blocking layer 72 is provided on the first light-transmitting resin layer 74 so as to be in direct contact therewith. The second light-blocking layer 72 is provided with the second opening OP2 in a region overlapping the photodiode 30 and the first opening OP1. The second opening OP2 is formed in a region overlapping the optical axis CL. More preferably, the center of the second opening OP2 and the center of the first opening OP1 are provided so as to overlap the optical axis CL.

The second light-blocking layer 72 is formed of, for example, a resin material colored in black. With the above-described configuration, the second light-blocking layer 72 serves as a light-absorbing layer that absorbs the components of the light L2 traveling in the oblique directions other than the light L2 passing through the second opening OP2. The second light-blocking layer 72 also absorbs light reflected by the first light-blocking layer 71. With this configuration, as compared with a configuration in which the second light-blocking layer 72 is formed of a metal material, the light reflected by the first light-blocking layer 71 can be restrained from being repeatedly reflected a plurality of number of times, traveling as stray light through the first light-transmitting resin layer 74, and entering the other photodiodes 30. The second light-blocking layer 72 can also absorb outside light incident from between the adjacent lenses 78. Thus, as compared with the configuration in which the second light-blocking layer 72 is formed of a metal material, the reflected light can be reduced in the second light-blocking layer 72. However, the second light-blocking layer 72 is not limited to the example of being formed of a resin material colored in black, and may be formed of a metal material having blackened surfaces.

The second light-transmitting resin layer 75 is provided on the second light-blocking layer 72 so as to be in direct contact therewith, and is provided between the second light-blocking layer 72 and the lens 78 in the third direction Dz.

The same material as that of the first light-transmitting resin layer 74 is used for the second light-transmitting resin layer 75, and thus, the refractive index of the second light-transmitting resin layer 75 is substantially equal to the refractive index of the first light-transmitting resin layer 74. As a result, the light L2 can be restrained from being reflected on an interface between the first light-transmitting resin layer 74 and the second light-transmitting resin layer 75 in the second opening OP2. However, the first light-transmitting resin layer 74 and the second light-transmitting resin layer 75 are not limited to this configuration, and may be formed of different materials, and the refractive index of the first light-transmitting resin layer 74 may differ from that of the second light-transmitting resin layer 75.

In the present embodiment, the width decreases in the order of a width W3 (diameter) in the first direction Dx of the lens 78, a width W2 (diameter) in the first direction Dx of the second opening OP2, and the width W1 (diameter) in the first direction Dx of the first opening OP1. The width W1 in the first direction Dx of the first opening OP1 is smaller than the width in the first direction Dx of the partial photodiode 30S-1 of the photodiode 30. The width W1 is from 2 μm to 10 μm, and is approximately 3.5 μm, for example. The width W2 is from 3 μm to 20 μm, and is approximately 10.0 μm, for example. The width W3 is from 10 μm to 50 μm, and is approximately 21.9 μm, for example.

A thickness TH2 of the second light-transmitting resin layer 75 illustrated in FIG. 5 is made substantially the same as a thickness TH1 of the first light-transmitting resin layer 74 or smaller than the thickness TH1 of the first light-transmitting resin layer 74. The thickness TH1 of the first light-transmitting resin layer 74 and the thickness TH2 of the second light-transmitting resin layer 75 are made larger than a thickness TH4 of the filter layer 73. The thickness TH1 of the first light-transmitting resin layer 74 and the thickness TH2 of the second light-transmitting resin layer 75 are larger than a thickness TH3 of the protective film 29 of the array substrate 2. The thickness TH1 and the thickness TH2 are from 3 μm to 30 μm, and more preferably from 10 μm to 30 μm. For example, the thickness TH1 is approximately 18 μm. The thickness TH2 is approximately 16.5 μm, for example. The thickness TH3 is from 1 μm to 10 μm, and is equal to or larger than 4.5 μm, for example. The thickness TH4 of the filter layer 73, as an example, is from 1 μm to 5 μm, and is 1.35 μm, for example.

With the above-described configuration, light L2-1 traveling in the third direction Dz among rays of the light L2 reflected by the object to be detected such as the finger Fg is condensed by the lens 78, and passes through the second opening OP2 and the first opening OP1 to enter the photodiode 30. Light L2-2 tilted by an angle θ1 from the third direction Dz also passes through the second opening OP2 and the first opening OP1 to enter the photodiode 30.

The projection PS is provided in a position that overlaps a portion of the first light-blocking layer 71 not provided with the first opening OP1 and a portion of the second light-blocking layer 72 not provided with the second opening OP2. The projection PS overlaps neither the first opening OP1 nor the second opening OP2, and the light L2 having passed through the projection PS is blocked by the first light-blocking layer 71 and the second light-blocking layer 72. Even when the detection device 1 has the configuration provided with the projection PS, the detection device 1 can restrain the detection accuracy from decreasing.

A width W4 (diameter) in the first direction Dx of the projection PS is equal to the width W3 (diameter) in the first direction Dx of the lens 78. In the third direction Dz, a height HL2 of the projection PS is larger than a height HL1 of the lens 78. In the third direction Dz, the top of the projection PS is provided in a position higher than the top of the lens 78. The projection PS is formed of a resin material, and is patterned into a columnar shape using a photolithography technique. In FIG. 5, the upper surface of the projection PS is formed to be flat. FIG. 5 is, however, merely schematically illustrated. The upper surface of the projection PS may have a curved surface in the same manner as the lens 78.

The optical filter 7 is formed integrally with the array substrate 2. That is, the first light-blocking layer 71 of the optical filter 7 is provided on the protective film 29 so as to be in direct contact therewith, and no member such as an adhesive layer is provided between the first light-blocking layer 71 and the protective film 29. Since the optical filter 7 is directly formed on the array substrate 2 and applying thereto a process such as patterning, the positional accuracy of the first opening OP1, the second opening OP2, and the lens 78 of the optical filter 7 relative to the photodiode 30 can be more improved than in a case where the optical filter 7 is attached as a separate body to the array substrate 2. The optical filter 7 is, however, not limited to this configuration, and may be what is called an external optical filter attached to the protective film 29 of the array substrate 2 with an adhesive layer interposed therebetween.

The optical filter 7 is also not limited to the configuration including the first light-blocking layer 71 and the second light-blocking layer 72, and may be formed including only one light-blocking layer. Although the filter layer 73 is provided between the first light-blocking layer 71 and the first light-transmitting resin layer 74, the position of the filter layer 73 is not limited to this position. The position of the filter layer 73 can be changed as appropriate depending on the characteristics required for the optical filter 7 and the manufacturing process.

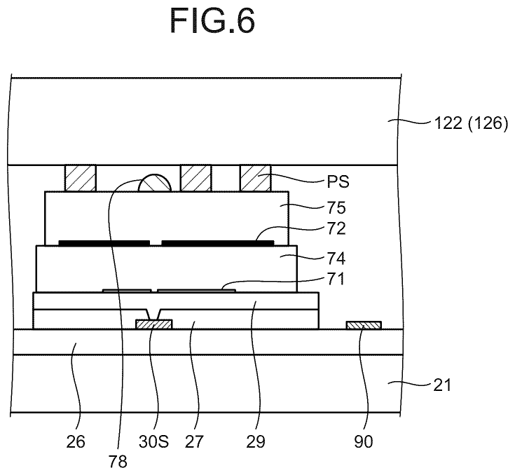

FIG. 6 is a sectional view schematically illustrating a configuration of the array substrate attached to the display panel, as illustrated in the example illustrated in FIG. 1B, for example. As illustrated in FIG. 6, the substrate 21 and a display panel 126 are attached together such that the projection PS abuts on the lower surface of the display panel 126. This configuration allows the detection device 1 to suppress damage of the lens 78 due to contact with the display panel 126.

The thicknesses of the layers of the optical filter 7, the width W1 of the first opening OP1, and the width W2 of the second opening OP2 illustrated in FIG. 5 can be changed as appropriate according to characteristics required for the optical filter 7. Other members such as the cover member 122 may be stacked instead of the display panel 126 illustrated in FIG. 6.

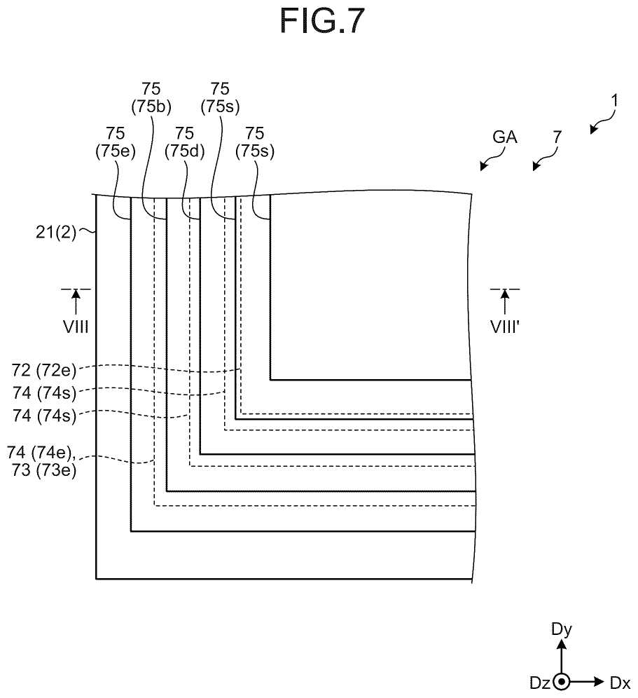

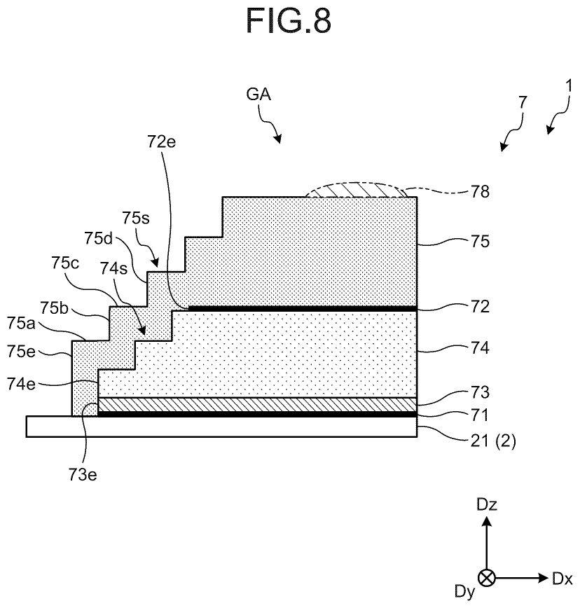

The following describes a detailed configuration of the optical filter 7 on the peripheral side of the array substrate 2. FIG. 7 is a plan view schematically illustrating the array substrate and the optical filter in the peripheral region. FIG. 8 is a sectional view illustrating the optical filter in the peripheral region. As illustrated in FIGS. 7 and 8, the first light-blocking layer 71, the filter layer 73, the first light-transmitting resin layer 74, the second light-blocking layer 72, and the second light-transmitting resin layer 75 are stacked in this order on the peripheral side of the array substrate 2.

In the example illustrated in FIGS. 7 and 8, on the peripheral side of array substrate 2, the second light-transmitting resin layer 75 is provided so as to cover an end on the peripheral side of the first light-blocking layer 71, an end 72e on the peripheral side of the second light-blocking layer 72, an end 74e on the peripheral side of the first light-transmitting resin layer 74, and an end 73e on the peripheral side of the filter layer 73. An end 75e on the peripheral side of the second light-transmitting resin layer 75 is in contact with the top of the array substrate 2. The end 75e on the peripheral side of the second light-transmitting resin layer 75, the end 74e on the peripheral side of the first light-transmitting resin layer 74 and the end 73e on the peripheral side of the filter layer 73, and the end 72e on the peripheral side of the second light-blocking layer 72 are arranged in this order in the first direction Dx from the peripheral side of the array substrate 2 toward the detection region AA.

A region on the peripheral side (periphery) of the first light-transmitting resin layer 74 and a region on the peripheral side of the second light-transmitting resin layer 75 are each formed in a stepped shape with a plurality of steps 74s and a plurality of steps 75s, respectively. Specifically, the steps 75s of the second light-transmitting resin layer 75 are formed by connecting at least a first upper surface 75a, a first side surface 75b, a second upper surface 75c, and a second side surface 75d from the end 75e on the peripheral side of the second light-transmitting resin layer 75. The height of each of the steps 75s (for example, the distance between the first upper surface 75a and the second upper surface 75c in the third direction Dz) is smaller than the width of the step 75s (for example, the distance between the first side surface 75b and the second side surface 75d in the first direction Dx). As an example, the height of the step 75s is approximately 5 μm, and the width of the step 75s is approximately 40 μm.

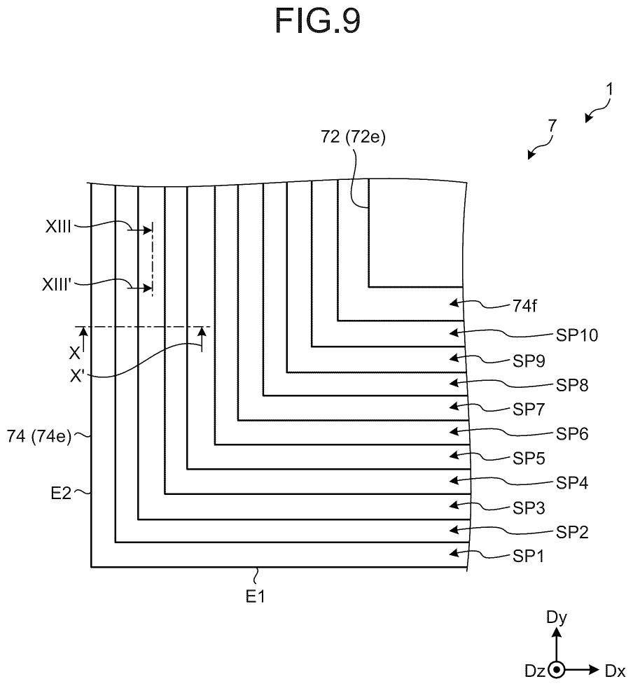

While the steps 75s of the second light-transmitting resin layer 75 have been described, the description of the steps 75s is also applicable to the steps 74s of the first light-transmitting resin layer 74. As a result, the end 74e on the peripheral side of the first light-transmitting resin layer 74 and the end 75e on the peripheral side of the second light-transmitting resin layer 75 are smoothly formed. FIGS. 7 and 8 are illustrated in a simplified manner to facilitate the understanding of the explanation. A detailed configuration of the periphery of the first light-transmitting resin layer 74 will be described with reference to FIG. 9 and the subsequent drawings.

The configuration of the second light-transmitting resin layer 75 covering the end 74e on the peripheral side of the first light-transmitting resin layer 74 has been described, but the configuration is not limited thereto. The second light-transmitting resin layer 75 only needs to be provided so as to cover at least the end 72e on the peripheral side of the second light-blocking layer 72. The end 74e on the peripheral side of the first light-transmitting resin layer 74 is provided in a position overlapping the end on the peripheral side of the first light-blocking layer 71 and the end 73e on the peripheral side of the filter layer 73, but is not limited to this configuration. The end 74e on the peripheral side of the first light-transmitting resin layer 74 may be provided, for example, so as to cover the end on the peripheral side of the first light-blocking layer 71 and the end 73e on the peripheral side of the filter layer 73.

FIG. 9 is a plan view illustrating a portion of the periphery of the first light-transmitting resin layer in an enlarged manner. As illustrated in FIG. 9, the first light-transmitting resin layer 74 includes a flat portion 74f provided at least in a region overlapping the detection region AA and a periphery formed to be gradually thinner toward the end 74e on the peripheral side of the first light-transmitting resin layer 74. The thickness TH1 of the first light-transmitting resin layer 74 described above with reference to FIG. 5 is the thickness TH1 at the flat portion 74f. While FIG. 9 illustrates a corner of the first light-transmitting resin layer 74 in an enlarged manner, the periphery is provided so as to surround the flat portion 74f.

In more detail, the end 74e on the peripheral side of the first light-transmitting resin layer 74 includes a first side E1 extending along the first direction Dx and a second side E2 extending along the second direction Dy. The periphery of the first light-transmitting resin layer 74 includes a region extending along the first edge E1 and a region extending along the second edge E2.

The periphery of the first light-transmitting resin layer 74 includes a plurality of partial peripheral regions SP1, SP2, . . . , SP10. In the region extending along the first side E1, the partial peripheral regions SP1, SP2, . . . , SP10 extend along the first side E1 of the first light-transmitting resin layer 74 and are arranged to be lined up in a direction intersecting the first side E1. In the region extending along the second side E2, the partial peripheral regions SP1, SP2, . . . , SP10 extend along the second side E2 of the first light-transmitting resin layer 74 and are arranged to be lined up in a direction intersecting the second side E2. The partial peripheral regions SP1, SP2, . . . , SP10 have different heights from one another, and are formed to be gradually thinner from the partial peripheral region SP10 adjacent to the flat portion 74f toward the partial peripheral region SP1 adjacent to the end 74e on the peripheral side. In the following description, the partial peripheral regions SP1, SP2, . . . , SP10 may each be simply referred to as the partial peripheral region SP when need not be distinguished from one another.

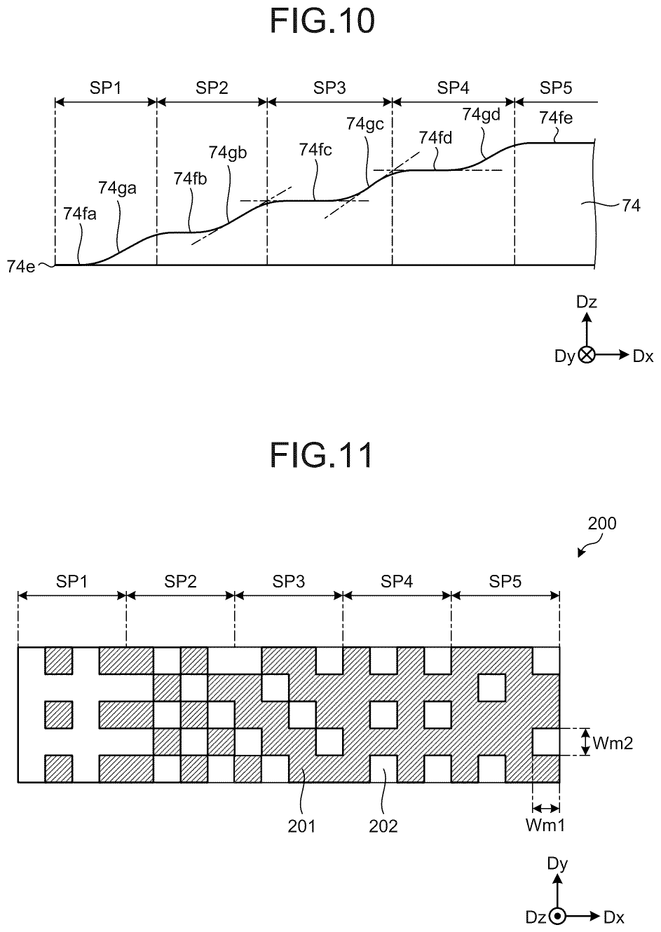

FIG. 10 is a sectional view along X-X′ of FIG. 9. As illustrated in FIG. 10, the first light-transmitting resin layer 74 has a gently stepped sectional shape. One partial peripheral region SP1 includes a first surface 74fa and a second surface 74ga that is connected to the first surface 74fa and has a larger inclination angle than that of the first surface 74fa. The partial peripheral regions SP1, SP2, SP3, SP4, and SP5 also include first surfaces 74fb, 74fc, 74fd, and 74fe, and second surfaces 74gb, 74gc, 74gd, and 74ge, respectively (the second surface 74ge is not illustrated in FIG. 10). The first surfaces 74fa, 74fb, 74fc, 74fd, and 74fe and the second surfaces 74ga, 74gb, 74gc, 74gd, and 74ge of the partial peripheral regions SP are alternately arranged to form the first light-transmitting resin layer 74 into a stepped shape.

The first light-transmitting resin layer 74 has a gently stepped shape, and boundaries between the partial peripheral regions SP can be set in any manner. For example, to explain a boundary between the peripheral regions SP2 and SP3, the boundary is set at the intersection between the tangent line of the second surface 74gb of the partial peripheral region SP2 and the tangent line of the first surface 74fc of the partial peripheral region SP3.

FIG. 11 is a plan view schematically illustrating a portion of a photomask used for manufacturing the first light-transmitting resin layer. As illustrated in FIG. 11, a photomask 200 includes light-blocking regions 201 and a plurality of open regions 202. Each of the open regions 202 has a rectangular pattern having a width Wm1 in the first direction Dx and a width Wm2 in the second direction Dy, and the open regions 202 are formed so as to be spaced in the first direction Dx and the second direction Dy. That is, the light-blocking regions 201 and the open regions 202 are repeatedly alternately arranged in the first direction Dx and also repeatedly alternately arranged in the second direction Dy.

The widths Wm1 and Wm2 of the open region 202 are formed sufficiently smaller than the width in the first direction Dx of the partial peripheral region SP. In FIG. 11, the open region 202 is illustrated to have a larger area to facilitate viewing of the figure, but in reality, the widths Wm1 and Wm2 of the open region 202 are several micrometers (for example, approximately 2 μm). The open region 202 is formed assuming one rectangular pattern having the widths Wm1 and Wm2 as the minimum unit. The open regions 202 are formed to be spaced at intervals of the minimum unit, and in some regions (for example, regions corresponding to the partial peripheral regions SP1 and SP2), more than one of the open regions 202 are connected to form a grid-like opening pattern.

The photomask 200 has a different arrangement pattern and area ratio of the open regions 202 for each of the partial peripheral regions SP. For example, a region corresponding to the partial peripheral region SP1 has an aperture ratio of 70%; a region corresponding to the partial peripheral region SP2 has an aperture ratio of 50%; a region corresponding to the partial peripheral region SP3 has an aperture ratio of 33%; a region corresponding to the partial peripheral region SP4 has an aperture ratio of 25%; and a region corresponding to the partial peripheral region SP5 has an aperture ratio of 16.7%.

Thus, the photomask 200 has the open regions 202 randomly arranged in the first direction Dx and the second direction Dy, and has the different arrangement pattern for each of the partial peripheral regions SP. This configuration allows the photomask 200 to reduce variations in distribution of the open regions 202 when a certain region is randomly selected. For example, compared with a photomask in which the open regions 202 are continuously formed in a stripe pattern in a predetermined direction, the photomask 200 of the present embodiment can restrain the open regions 202 from being biased in both the first direction Dx and the second direction Dy.

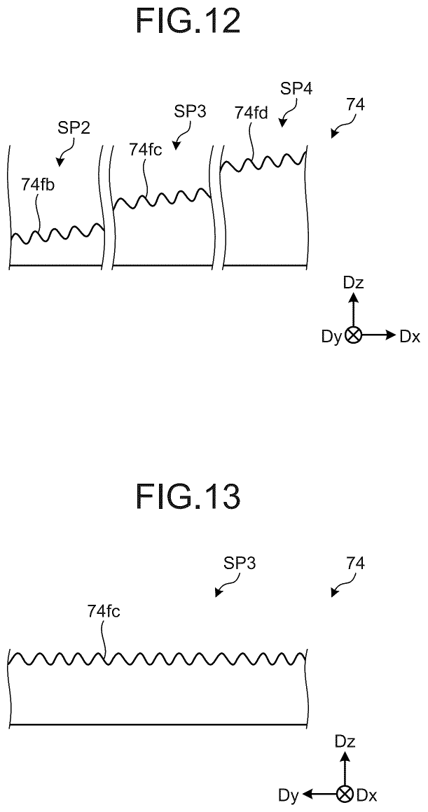

FIG. 12 is a sectional view for explaining asperity patterns in the first direction Dx of the first light-transmitting resin layer. FIG. 13 is a sectional view along XIII-XIII′ of FIG. 9, and is a sectional view for explaining an asperity pattern in the second direction Dy of the first light-transmitting resin layer. FIGS. 12 and 13 illustrate a portion of the region extending along the second side E2 (refer to FIG. 9) in the periphery of the first light-transmitting resin layer 74 in an enlarged manner. More specifically, FIG. 12 is a sectional view illustrating the partial peripheral regions SP2, SP3, and SP4 in an enlarged manner. FIG. 13 is a sectional view illustrating the partial peripheral region SP3 in an enlarged manner.

As the open regions 202, the rectangular patterns each having the widths Wm1 and Wm2 are randomly arranged in the first direction Dx and the second direction Dy. With this arrangement, a plurality of asperity patterns according to the open regions 202 are repeatedly formed in the first light-transmitting resin layer 74. Although FIGS. 12 and 13 illustrate the asperity patterns in a highlighted manner in order to facilitate understanding, the height of each of the asperity patterns is made sufficiently smaller than a step for each of the partial peripheral regions SP.

As illustrated in FIG. 12, the asperity patterns are repeatedly formed in the first direction Dx on each of the first surfaces 74fb, 74fc, and 74fd of the partial peripheral regions SP2, SP3, and SP4, respectively. As illustrated in FIG. 13, the asperity patterns are repeatedly formed in the second direction Dy on the first surface 74fc of the partial peripheral region SP3. That is, in a region of the periphery of the first light-transmitting resin layer 74 extending along a predetermined side (for example, the second side E2 (refer to FIG. 9)), the asperity patterns are repeatedly formed in the direction intersecting the side (first direction Dx) and repeatedly formed in the direction along the side (second direction Dy).

Although not illustrated in FIGS. 12 and 13, the asperity patterns are repeatedly formed in the first direction Dx and the second direction Dy in the other partial peripheral regions SP in the same way. The region of the periphery of the first light-transmitting resin layer 74 extending along the second side E2 is illustrated in FIGS. 12 and 13. Also, in the region extending along the first edge E1, the asperity patterns are repeatedly formed in the first direction Dx and the second direction Dy in the same way.

As described above, the photomask 200 can appropriately set the aperture ratio for each of the partial peripheral regions SP, and can restrain the first light-transmitting resin layer 74 from being exposed to light in a biased manner. The minimum resolution of the photomask 200 can be ensured by arranging the open regions 202 in the first direction Dx and the second direction Dy assuming the rectangular pattern having the widths Wm1 and Wm2 as the minimum unit. As a result, the first light-transmitting resin layer 74 has no steep steps formed thereon, and is formed as a whole in a gentle step shape as illustrated in FIG. 10.

As a result, non-uniformity of shapes of the second light-blocking layer 72 (second opening OP2) and the lenses 78 caused by variations in shape of the periphery of the first light-transmitting resin layer 74 can be reduced when the second light-blocking layer 72 and the lenses 78 are formed by coating. Therefore, the detection device 1 can reduce the variation of the light L2 focused on the photodiode 30 (partial photodiode 30S) through the lens 78 and the second opening OP2, and thus can restrain the detection accuracy from decreasing.

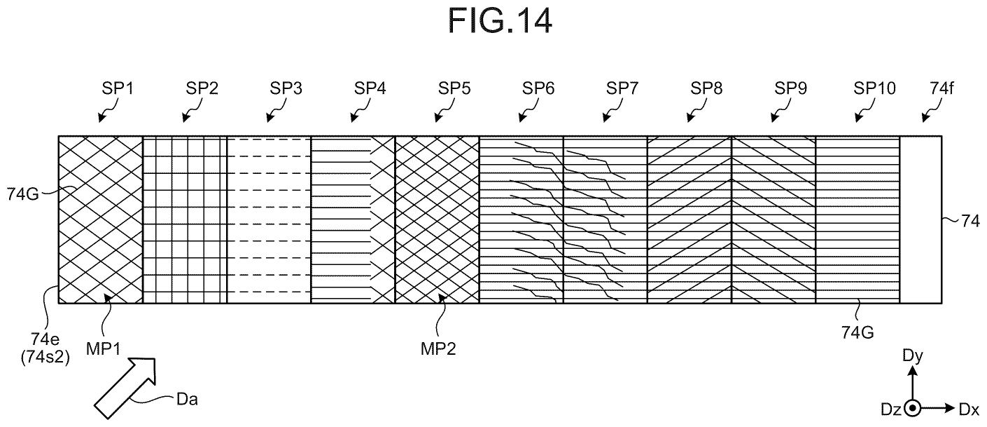

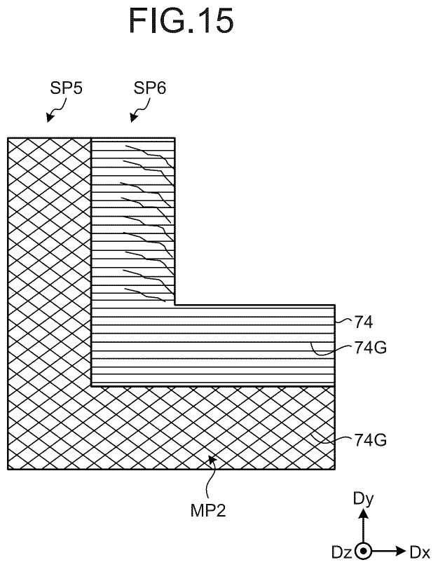

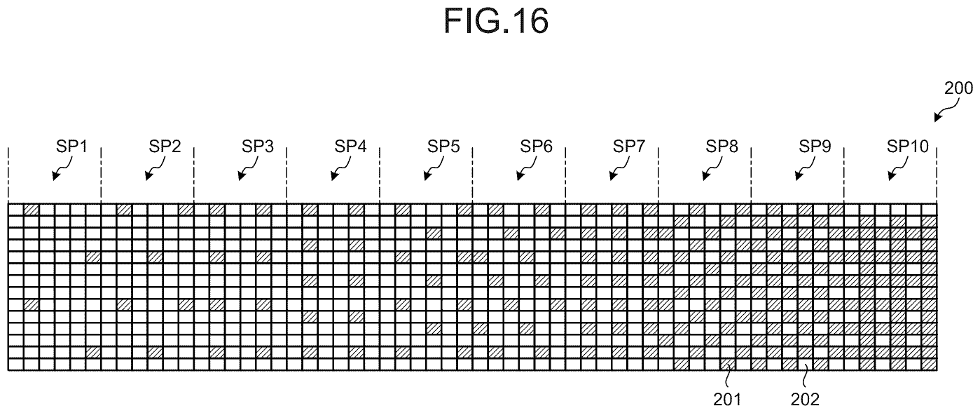

The following describes, in detail, an example of the asperity patterns formed on the periphery of the first light-transmitting resin layer 74. FIG. 14 is a plan view for explaining the example of the asperity patterns on the periphery of the first light-transmitting resin layer. FIG. 15 is a plan view for explaining an example of the asperity patterns on a corner of the periphery of the first light-transmitting resin layer. FIG. 16 is a plan view schematically illustrating a portion of the photomask used for manufacturing the first light-transmitting resin layer illustrated in FIGS. 14 and 15. FIG. 14 illustrates the partial peripheral regions SP of the periphery of the first light-transmitting resin layer 74 extending along the second side E2. FIG. 15 illustrates the partial peripheral regions SP5 and SP6 at the corner of the periphery of the first light-transmitting resin layer 74. FIGS. 14 and 15 schematically illustrate asperity patterns 74G.

As illustrated in FIGS. 14 and 15, in plan view, the asperity pattern 74G is formed in each of the partial peripheral regions SP, and the different asperity patterns 74G are formed in at least two adjacent regions of the partial peripheral regions SP. The different asperity patterns are formed due to, for example, the following effects: the arrangement pattern of the light-blocking regions 201 and the open regions 202 of the photomask 200 (refer to FIG. 16); the direction of flow of a coating liquid when manufacturing the second light-blocking layer 72 and the lenses 78 (for example, direction of an arrow Da in FIG. 14); and the interference of diffracted light when exposing the first light-transmitting resin layer 74.

In more detail, as illustrated in the example in FIG. 14, in the partial peripheral region SP1 located on the most peripheral side of the first light-transmitting resin layer, a rhombic asperity pattern MP1 in which the asperity patterns 74G extend while diagonally intersecting each other is formed to be visible. In the partial peripheral region SP2 adjacent to the partial peripheral region SP1, a ladder-like (or grid-like) asperity pattern in which the asperity patterns 74G extend in the first direction Dx and the second direction Dy is formed to be visible. In the partial peripheral region SP3, a dashed line-shaped asperity pattern in which the asperity patterns 74G extending in the first direction Dx are formed with gaps at predetermined intervals is formed to be visible. In the partial peripheral region SP4, a horizontal streak-like asperity pattern having the asperity patterns 74G extending in the first direction Dx and the rhombic asperity patterns MP1 are formed to be visible. That is, a linear asperity pattern is formed to be visible in each of the partial peripheral regions (for example, the partial peripheral regions SP2, SP3, and SP4) between the flat portion 74f and the partial peripheral region SP1 located on the most peripheral side of the first light-transmitting resin layer 74. The term “visible” refers to being identifiable with a microscope.

In the partial peripheral region SP5, rhombic asperity patterns MP2 in which the asperity patterns 74G extend while diagonally intersecting each other is formed to be visible. The rhombic asperity patterns MP2 have a smaller arrangement pitch than that of the rhombic asperity patterns MP1 of the partial peripheral region SP1. That is, the rhombic asperity pattern MP2 having a different arrangement pitch is formed to be visible in a partial peripheral region (for example, the partial peripheral region SP5) between the flat portion 74f and the partial peripheral region SP1 located on the most peripheral side of the first light-transmitting resin layer 74.

In each of the partial peripheral regions SP6 and SP7, a pattern obtained by combining a horizontal streak-like asperity pattern in which the asperity patterns 74G extend in the first direction Dx with an asperity pattern in which the asperity patterns 74G diagonally extend (toward a lower right direction in FIG. 14) is formed to be visible. In the partial peripheral region SP8, a pattern obtained by combining a horizontal streak-like asperity pattern in which the asperity patterns 74G extend in the first direction Dx with an asperity pattern in which the asperity patterns 74G diagonally extend (toward a lower left direction in FIG. 14) is formed to be visible. In the partial peripheral region SP9, a pattern obtained by combining a horizontal streak-like asperity pattern in which the asperity patterns 74G extend in the first direction Dx with an asperity pattern in which the asperity patterns 74G diagonally extend (toward a lower right direction in FIG. 14) is formed to be visible. In the partial peripheral region SP10, a horizontal streak-like asperity pattern in which the asperity patterns 74G extend in the first direction Dx is formed to be visible.

The asperity pattern 74G diagonally extending in each of the partial peripheral regions SP8 and SP9 is formed so as to look more linear than the asperity pattern 74G diagonally extending in each of the partial peripheral regions SP6 and SP7. The horizontal streak-like asperity pattern 74G in each of the partial peripheral regions SP6 to SP10 has a smaller arrangement pitch than that of the horizontal streak-like asperity pattern 74G in each of the partial peripheral regions SP2, SP3, and SP4.

As illustrated in FIG. 15, in the partial peripheral region SP6 as one of two adjacent partial peripheral regions (for example, the partial peripheral regions SP5 and SP6), the asperity patterns 74G different between the region extending along the first side E1 (refer to FIG. 9) and the region extending along the second side E2 (refer to FIG. 9) are formed to be visible. In the region of the partial peripheral region SP6 extending along the first side E1 (refer to FIG. 9), the pattern is a horizontal streak-like asperity pattern, and in the region of the partial peripheral region SP6 extending along the second side E2 (refer to FIG. 9), the pattern is a pattern obtained by combining the horizontal streak-like asperity pattern with an asperity pattern that extends diagonally (toward a lower right direction in FIG. 14).

In the other partial peripheral region SP5, the region extending along the first side E1 (refer to FIG. 9) and the region extending along the second side E2 (refer to FIG. 9) have the same asperity pattern. The region extending along the first side E1 (refer to FIG. 9) and the region extending along the second side E2 (refer to FIG. 9) of the partial peripheral region SP5 have the same rhombic asperity pattern MP2.

While FIG. 15 illustrates the partial peripheral regions SP5 and SP6, the other partial peripheral regions SP may also have the different asperity patterns 74G in one partial peripheral region SP.

As illustrated in FIG. 16, the photomask 200 has a different arrangement pattern of a plurality of the light-blocking regions 201 and the open regions 202 for each of the partial peripheral regions SP. The aperture ratio of the photomask 200 increases from a region corresponding to the partial peripheral region SP10 toward a region corresponding to the partial peripheral region SP1.

As described above, the asperity pattern 74G formed on the periphery of the first light-transmitting resin layer 74 differs for each of the partial peripheral regions SP, or at least one of the partial peripheral regions SP may have the asperity pattern 74G different from that of another region. This configuration randomly forms the asperity pattern 74G on the periphery of the first light-transmitting resin layer 74. Therefore, compared with a case where the asperity pattern 74G is formed regularly on the periphery of the first light-transmitting resin layer 74, when the second light-blocking layer 72 and the lenses 78 are formed by coating, anisotropy in shapes of the second light-blocking layer 72 (second opening OP2) and the lenses 78, such as uneven stripes, can be restrained from occurring due to the asperity pattern 74G on the periphery of the first light-transmitting resin layer 74.

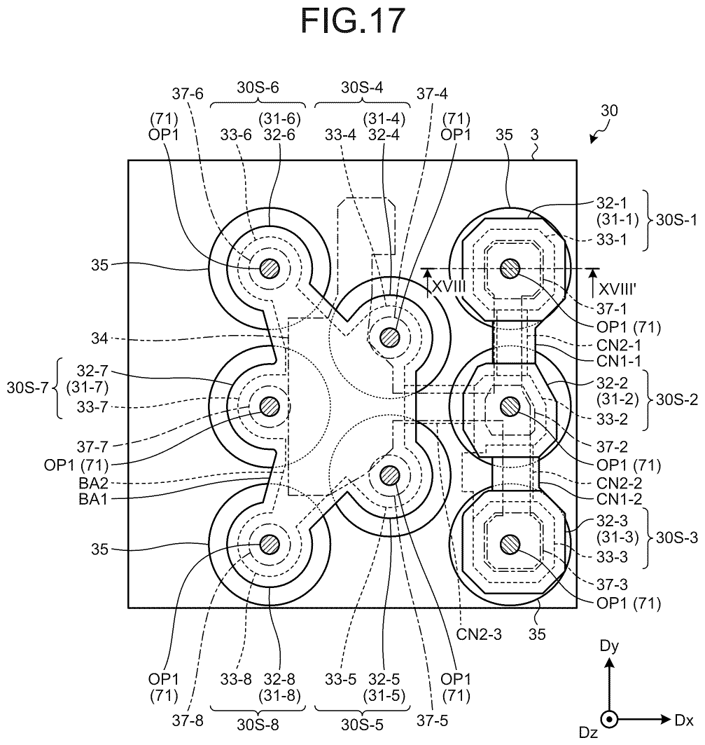

FIG. 17 is a plan view illustrating the detection element. To facilitate viewing, FIG. 17 is illustrated without a plurality of transistors included in the detection element 3 and various types of wiring such as scan lines and signal lines. Each of the detection elements 3 is defined, for example, as a region surrounded by the scan lines and the signal lines.

As illustrated in FIG. 17, the photodiode 30 includes a plurality of partial photodiodes 30S-1, 30S-2, . . . , 30S-8. The partial photodiodes 30S-1, 30S-2, . . . , 30S-8 are arranged in a triangular lattice pattern. The lenses 78-1, 78-2, . . . , 78-8 illustrated in FIG. 4, the first openings OP1 of the first light-blocking layer 71, and the second openings OP2 of the second light-blocking layer 72 are provided so as to overlap the respective partial photodiodes 30S-1, 30S-2, . . . , 30S-8.

More specifically, the partial photodiodes 30S-1, 30S-2, and 30S-3 are arranged in the second direction Dy. The partial photodiodes 30S-4 and 30S-5 are arranged in the second direction Dy, and are adjacent in the first direction Dx to an element column that includes the partial photodiodes 30S-1, 30S-2, and 30S-3. The partial photodiodes 30S-6, 30S-7, and 30S-8 are arranged in the second direction Dy, and are adjacent in the first direction Dx to an element column that includes the partial photodiodes 30S-4 and 30S-5. The positions in the second direction Dy of the partial photodiodes 30S are arranged in a staggered manner between the adjacent element columns.

The light L2 is incident on the partial photodiodes 30S-1, 30S-2, . . . , 30S-8 from the lenses 78-1, 78-2, . . . , 78-8, respectively. The partial photodiodes 30S-1, 30S-2, . . . , 30S-8 are electrically coupled to one another to serve as one photodiode 30. That is, signals output from the respective partial photodiodes 30S-1, 30S-2, . . . , 30S-8 are integrated into one detection signal to be output from the photodiode 30. In the following description, the partial photodiodes 30S-1, 30S-2, . . . , 30S-8 will be simply referred to as the partial photodiodes 30S when need not be distinguished from one another.

Each of the partial photodiodes 30S includes an i-type semiconductor layer 31, an n-type semiconductor layer 32, and a p-type semiconductor layer 33. The i-type semiconductor layer 31 and the n-type semiconductor layer 32 are formed of amorphous silicon (a-Si), for example. The p-type semiconductor layer 33 is formed of polysilicon (p-Si), for example. The material of each of the semiconductor layers is not limited to those mentioned above, and may be, for example, polysilicon or microcrystalline silicon.

The a-Si of the n-type semiconductor layer 32 is doped with impurities to form an n+ region. The a-Si of the p-type semiconductor layer 33 is doped with impurities to form a p+ region. The i-type semiconductor layer 31 is, for example, a non-doped intrinsic semiconductor, and has lower electric conductivity than those of the n-type semiconductor layer 32 and the p-type semiconductor layer 33.

FIG. 17 uses a long dashed short dashed line to illustrate an effective sensor region 37 in which the p-type semiconductor layer 33 is coupled to the i-type semiconductor layer 31 (n-type semiconductor layer 32). The first opening OP1 of the first light-blocking layer 71 is provided so as to overlap the sensor region 37.

The partial photodiodes 30S have different shapes from one another in plan view. The partial photodiodes 30S-1, 30S-2, and 30S-3 are each formed in a polygonal shape. The partial photodiodes 30S-4, 30S-5, 30S-6, 30S-7, and 30S-8 are each formed in a circular shape or a semi-circular shape.

The n-type semiconductor layers 32 of the partial photodiodes 30S-1, 30S-2, and 30S-3 arranged in the second direction Dy are electrically coupled together by joints CN1-1 and CN1-2. The p-type semiconductor layers 33 of the partial photodiodes 30S-1, 30S-2, and 30S-3 are electrically coupled together by joints CN2-1 and CN2-2.

The n-type semiconductor layers 32 (i-type semiconductor layers 31) of the partial photodiodes 30S-4, 30S-5, 30S-6, 30S-7, and 30S-8 are electrically coupled together by a base BA1. The p-type semiconductor layers 33 of the partial photodiodes 30S-4, 30S-5, 30S-6, 30S-7, and 30S-8 are electrically coupled together by a base BA2. Each of the bases BA1 and BA2 is formed in a substantially pentagonal shape, and is provided, in the apex positions thereof, with the partial photodiodes 30S-4, 30S-5, 30S-6, 30S-7, and 30S-8. The base BA2 is electrically coupled to the p-type semiconductor layers 33 of the partial photodiodes 30S-1, 30S-2, and 30S-3 by a joint CN2-3. The above-described configuration electrically couples together the partial photodiodes 30S constituting one photodiode 30.

A lower conductive layer 35 is provided in a region overlapping each of the partial photodiodes 30S. The lower conductive layers 35 are all circular in plan view. That is, the lower conductive layer 35 may have a different shape from that of the partial photodiode 30S. For example, each of the partial photodiodes 30S-1, 30S-2, and 30S-3 has a polygonal shape in plan view, and is formed on the circular lower conductive layer 35. Each of the partial photodiodes 30S-4, 30S-5, 30S-6, 30S-7, and 30S-8 has a circular shape or a semi-circular shape having a diameter smaller than that of the lower conductive layer 35 in plan view, and is formed on the circular lower conductive layer 35. The lower conductive layer 35 is supplied with the reference potential VCOM that is the same as the potential of the p-type semiconductor layer 33, and thus, can reduce parasitic capacitance between the lower conductive layer 35 and the p-type semiconductor layer 33.

An upper conductive layer 34 electrically couples together the n-type semiconductor layers 32 of the partial photodiodes 30S. The upper conductive layer 34 is electrically coupled to the transistors (not illustrated) on the array substrate 2. The upper conductive layer 34 may be provided in any manner, and may be provided, for example, so as to cover a portion of the partial photodiode 30S, or so as to cover the entire partial photodiode 30S.

In the present embodiment, the partial photodiode 30S is provided for each of the lenses 78 and each of the first openings OP1. As compared with a configuration in which the photodiode 30 is formed of a solid film having, for example, a quadrilateral shape so as to cover the entire detection element 3 in plan view, this configuration can reduce the numbers of the semiconductor layers and wiring layers in regions not overlapping the lenses 78 and the first openings OP1, and therefore, can reduce the parasitic capacitance of the photodiodes 30.

The planar structure of the photodiode 30 illustrated in FIG. 17 is merely an example, and can be changed as appropriate. The number of the partial photodiodes 30S included in one photodiode 30 may be seven or smaller, or nine of larger. The partial photodiodes 30S are not limited to being arranged in a triangular lattice pattern, and may be arranged in a matrix having a row-column configuration, for example. The arrangement of the lenses 78, the first openings OP1, and the second openings OP2 included in the optical filter 7 can also be changed as appropriate depending on the configuration of the partial photodiodes 30S.

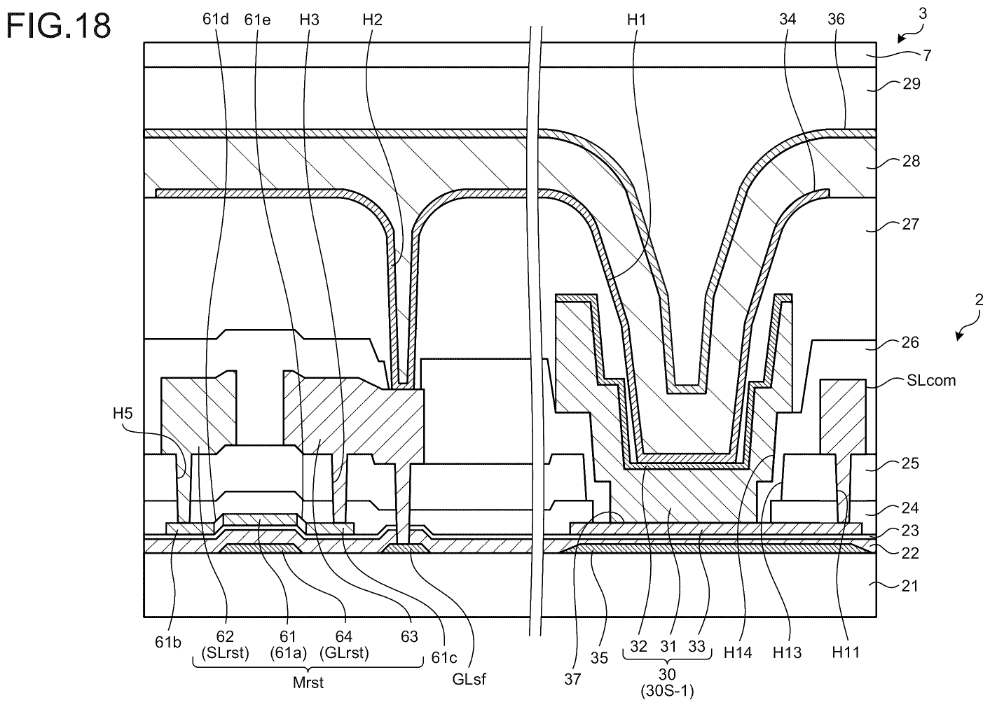

FIG. 18 is a sectional view along XVIII-XVIII′ of FIG. 17. FIG. 18 illustrates a sectional configuration of a transistor Mrst included in the detection element 3 together with a sectional configuration of the partial photodiode 30S-1.

The substrate 21 is an insulating substrate. A glass substrate of, for example, quartz or alkali-free glass, or a resin substrate of, for example, polyimide is used as the substrate 21. A gate electrode 64 is provided on the substrate 21. Insulating films 22 and 23 are provided above the substrate 21 so as to cover the gate electrode 64. The insulating films 22 and 23 and insulating films 24, 25, and 26 are inorganic insulating films, and are formed of, for example, silicon oxide (SiO₂) or silicon nitride (SiN).

A semiconductor layer 61 is provided on the insulating film 23. For example, polysilicon is used as the semiconductor layer 61. The semiconductor layer 61 is, however, not limited thereto, and may be formed of, for example, a microcrystalline oxide semiconductor, an amorphous oxide semiconductor, or low-temperature polycrystalline silicon (LTPS). The transistor Mrst has a bottom-gate structure in which the gate electrode 64 is provided below the semiconductor layer 61, but may have a top-gate structure in which the gate electrode 64 is provided above the semiconductor layer 61, or a dual-gate structure in which the gate electrodes 64 are provided above and below the semiconductor layer 61.

The semiconductor layer 61 includes a channel region 61a, high-concentration impurity regions 61b and 61c, and low-concentration impurity regions 61d and 61e. The channel region 61a is, for example, a non-doped intrinsic semiconductor or a low-impurity region, and has lower conductivity than that of the high-concentration impurity regions 61b and 61c and the low-concentration impurity regions 61d and 61e. The channel region 61a is provided in a region overlapping the gate electrode 64.

The insulating films 24 and 25 are provided above the insulating film 23 so as to cover the semiconductor layer 61. A source electrode 62 and a drain electrode 63 are provided above the insulating film 25. The source electrode 62 is coupled to the high-concentration impurity region 61b of the semiconductor layer 61 through a contact hole H5. The drain electrode 63 is coupled to the high-concentration impurity region 61c of the semiconductor layer 61 through a contact hole H3. The source and the drain electrodes 62 and 63 are formed of, for example, a multilayer film of Ti—Al—Ti layers or Ti—Al layers that is a multilayer structure of titanium and aluminum.

A gate line GLsf is wiring coupled to the gate of a source follower transistor Msf. The gate line GLsf is provided in the same layer as that of the gate electrode 64. The drain electrode 63 (coupling wiring SLcn) is coupled to the gate line GLsf through a contact hole passing through the insulating films 22 to 25.

The following describes a sectional configuration of the photodiode 30. While the partial photodiode 30S-1 will be described with reference to FIG. 18, the description of the partial photodiode 30S-1 is also applicable to the other partial photodiodes 30S-2, . . . , 30S-8. As illustrated in FIG. 18, the lower conductive layer 35 is provided in the same layer as that of the gate electrode 64 and the gate line GLsf on the substrate 21. The insulating films 22 and 23 are provided above the lower conductive layer 35. The photodiode 30 is provided on the insulating film 23, and the lower conductive layer 35 is provided between the substrate 21 and the p-type semiconductor layer 33. The lower conductive layer 35 is formed of the same material as that of the gate electrode 64 to serve as a light-blocking layer, and thus, the lower conductive layer 35 can restrain light from entering the photodiode 30 from the substrate 21 side.

The i-type semiconductor layer 31 is provided between the p-type semiconductor layer 33 and the n-type semiconductor layer 32 in the third direction Dz. In the present embodiment, the p-type semiconductor layer 33, the i-type semiconductor layer 31, and the n-type semiconductor layer 32 are stacked in this order above the insulating film 23. The effective sensor region 37 illustrated in FIG. 17 is a region in which the i-type semiconductor layer 31 is coupled to the p-type semiconductor layer 33.

Specifically, the p-type semiconductor layer 33 is provided in the same layer as that of the semiconductor layer 61 on the insulating film 23. The insulating films 24, 25, and 26 are provided so as to cover the p-type semiconductor layer 33. The insulating films 24 and 25 are provided with a contact hole H13 in a position overlapping the p-type semiconductor layer 33. The insulating film 26 is provided on the insulating film 25 so as to cover the transistors including the transistor Mrst. The insulating film 26 covers side surfaces of the insulating films 24 and 25 that form the inner wall of the contact hole H13. The insulating film 26 is provided with a contact hole H14 in a position overlapping the p-type semiconductor layer 33.

The i-type semiconductor layer 31 is provided on the insulating film 26 and is coupled to the p-type semiconductor layer 33 through the contact hole H14 penetrating the insulating films 24 to 26. The n-type semiconductor layer 32 is provided on the i-type semiconductor layer 31.

An insulating film 27 is provided on the insulating film 26 so as to cover the photodiode 30. The insulating film 27 is provided so as to be in direct contact with the photodiode 30 and the insulating film 26. The insulating film 27 is formed of an organic material such as a photosensitive acrylic. The insulating film 27 is thicker than the insulating film 26. The insulating film 27 has a better step covering property than that of inorganic insulating materials, and is provided so as to cover side surfaces of the i-type semiconductor layer 31 and the n-type semiconductor layer 32.

The upper conductive layer 34 is provided on the insulating film 27. The upper conductive layer 34 is formed of, for example, a light-transmitting conductive material such as indium tin oxide (ITO). The upper conductive layer 34 is provided along a surface of the insulating film 27, and is coupled to the n-type semiconductor layer 32 through a contact hole H1 provided in the insulating film 27. The upper conductive layer 34 is electrically coupled to the drain electrode 63 of the transistor Mrst and the gate line GLsf through a contact hole H2 provided in the insulating film 27.

An insulating film 28 is provided on the insulating film 27 so as to cover the upper conductive layer 34. The insulating film 28 is an inorganic insulating film. The insulating film 28 is provided as a protective layer for restraining water from entering the photodiode 30. An overlapping conductive layer 36 is provided on the insulating film 28. The overlapping conductive layer 36 is formed of, for example, a light-transmitting conductive material such as ITO. The overlapping conductive layer 36 may be excluded.

The protective film 29 is provided above the insulating film 28 so as to cover the overlapping conductive layer 36. The protective film 29 is an organic protective film. The protective film 29 is formed so as to planarize a surface of the detection device 1.

In the present embodiment, the p-type semiconductor layer 33 of the photodiode 30 and the lower conductive layer 35 are provided in the same layers as those of the transistors. Therefore, the manufacturing process can be made simpler than in a case where the photodiode 30 is formed in layers different from those of the transistors.

The sectional configuration of the photodiode 30 illustrated in FIG. 18 is merely an example. The sectional configuration is not limited to this example. For example, the photodiode 30 may be provided in layers different from those of the transistors, or may be provided by stacking the p-type semiconductor layer 33, the i-type semiconductor layer 31, and the n-type semiconductor layer 32 in this order on the insulating film 26.

In the embodiment described above, the configuration has been described in which a multilayer structure including the substrate 21, at least one light-transmitting resin layer (first light-transmitting resin layer 74) stacked on the substrate 21, and an optical functional layer stacked on the light-transmitting resin layer is applied to the detection device 1 including the photodiodes 30 and the optical filter 7, but the configuration is not limited this example. The multilayer structure can also be applied to other detection devices, optical elements, electronic apparatuses, and so forth.

One example of the multilayer structure is an array substrate of a liquid crystal display device including a color filter, such as a color filter on array (COA) described in Japanese Patent Application Laid-open Publication No. 2021-063897, for example. Alternatively, one example of the multilayer structure is a counter substrate of a liquid crystal display device including a color filter, such as a black matrix on color filter (BOC) structure described in Japanese Patent Application Laid-open Publication No. 2018-054733 or a black matrix on overcoat (BOO) structure described in Japanese Patent Application Laid-open Publication No. 2017-191276. In the array substrate having a COA structure, the light-transmitting resin layer corresponds to the color filter or a planarizing layer covering the color filter, and light-blocking wiring, a black matrix, or the like formed on the color filter or the planarizing layer corresponds to the optical functional layer. In the counter substrate having a BOC or BOO structure, the light-transmitting resin layer corresponds to the color filter or an overcoat layer, and the light-blocking layer (black matrix) formed on the color filter or the overcoat layer corresponds to the optical functional layer. As an example, the color filter used in the liquid crystal display device is approximately 1.5 μm thick, and the multilayer structure of the present disclosure can be applied to the color filter of 1 μm thick or thicker.

Furthermore, an example of the multilayer structure can be applied to a viewing angle control louver described in Japanese Patent Application Laid-open Publication No. 2011-141498. The viewing angle control louver also includes a thick light-transmitting resin layer and has a light-blocking layer (corresponding to the optical functional layer) that is formed by coating on a thick transparent resin layer, thus being applicable as the multilayer structure of the present disclosure.

While the preferred embodiment of the present disclosure has been described above, the present disclosure is not limited to the embodiment described above. The content disclosed in the embodiment is merely an example, and can be variously modified within the scope not departing from the gist of the present disclosure. Any modifications appropriately made within the scope not departing from the gist of the present disclosure also naturally belong to the technical scope of the present disclosure. At least one of various omissions, substitutions, and changes of the components can be made without departing from the gist of the embodiment and the modifications described above.

What is claimed is:

1. A detection device comprising:
a substrate having a detection region;
a plurality of photodiodes provided in the detection region;
a first light-transmitting resin layer that is provided so as to cover the photodiodes and comprises a flat portion and a periphery that is formed to be gradually thinner toward an end on a peripheral side of the first light-transmitting resin layer;
a light-blocking layer that is provided on the first light-transmitting resin layer and provided with an opening in a region overlapping each of the photodiodes; and
a plurality of lenses provided so as to overlap the respective photodiodes, wherein
in a region of the periphery of the first light-transmitting resin layer extending along a predetermined side, an asperity pattern is repeatedly formed in a direction intersecting the side and repeatedly formed in a direction along the side.

2. The detection device according to claim 1, wherein
the periphery of the first light-transmitting resin layer comprises a plurality of partial peripheral regions that extend along a side of the first light-transmitting resin layer, and are arranged to be lined up in a direction intersecting the side,
the asperity pattern is formed in each of the partial peripheral regions, and
different asperity patterns are formed in at least two adjacent regions of the partial peripheral regions.

3. The detection device according to claim 1, wherein
the periphery of the first light-transmitting resin layer comprises a plurality of partial peripheral regions that extend along a side of the first light-transmitting resin layer, and are arranged to be lined up in a direction intersecting the side,
the side of the first light-transmitting resin layer at least comprises a first side extending along a first direction and a second side extending along a second direction intersecting the first direction, and
in at least one of the partial peripheral regions, the asperity patterns different between a region extending along the first side and a region extending along the second side are formed.

4. The detection device according to claim 3, wherein
in two adjacent regions of the partial peripheral regions:
in one of the partial peripheral regions, the asperity patterns different between the region extending along the first side and the region extending along the second side are formed, and
in another of the partial peripheral regions, the same asperity pattern is formed in the region extending along the first side and the region extending along the second side.

5. The detection device according to claim 2, wherein
the asperity pattern has a rhombic shape and is formed in the partial peripheral region located on a most peripheral side of the first light-transmitting resin layer, and
the asperity pattern has a linear shape and is formed in the partial peripheral regions between the flat portion and the partial peripheral region located on the most peripheral side of the first light-transmitting resin layer.

6. The detection device according to claim 5, wherein the rhombic asperity pattern has a different arrangement pitch from an arrangement pitch of the partial peripheral region located on the most peripheral side and is formed in a partial peripheral region between the flat portion and the partial peripheral region located on the most peripheral side of the first light-transmitting resin layer.

7. The detection device according to claim 2, wherein
each of the partial peripheral regions comprises a first surface and a second surface that is connected to the first surface and has a larger inclination angle than an inclination angle of the first surface, and
the first surfaces and the second surfaces of the partial peripheral regions are alternately arranged.

8. The detection device according to claim 1, comprising a second light-transmitting resin layer provided so as to cover the light-blocking layer, wherein
the second light-transmitting resin layer is provided so as to cover an end on a peripheral side of the light-blocking layer and an end on the peripheral side of the first light-transmitting resin layer.

9. The detection device according to claim 8, comprising an infrared (IR) cut filter layer that is provided between the photodiodes and the first light-transmitting resin layer and is configured to block infrared rays, wherein
the first light-transmitting resin layer, the light-blocking layer, the second light-transmitting resin layer, and the lenses are stacked above the IR cut filter layer.

10. The detection device according to claim 1, wherein the flat portion of the first light-transmitting resin layer has a thickness of 10 μm or larger.

11. A multilayer structure comprising:
a substrate;
at least one light-transmitting resin layer that is stacked above the substrate and comprises a flat portion and a periphery that is formed to be gradually thinner toward an end on a peripheral side of the light-transmitting resin layer; and
an optical functional layer stacked on the light-transmitting resin layer, wherein
in a region of the periphery of the light-transmitting resin layer extending along a predetermined side, an asperity pattern is repeatedly formed in a direction intersecting the side and repeatedly formed in a direction along the side.

12. The multilayer structure according to claim 11, wherein the flat portion of the light-transmitting resin layer has a thickness of 10 μm or larger.
